(19) United States
(12) Patent Application Publication
(10) Pub. No.: US 2012/0280707 A1
(43) Pub. Date: Nov. 8, 2012

(54) BOARD MOUNTING APPARATUS, TEST HEAD, AND ELECTRONIC DEVICE TEST APPARATUS

(75) Inventors: Hideki Saito, Miyasi (JP); Kazuhiro Matsutani, Saitama (JP)

(73) Assignee: ADVANTEST CORPORATION, Tokyo (JP)

(21) Appl. No.: 13/511,725

(22) PCT Filed: Nov. 25, 2009
(86) PCT No.: PCT/JP2009/069857

§ 371 Date: Jul. 24, 2012

(51) Int. Cl. H05K 7/14; G01R 31/26

(52) U.S. Cl. 324/756.07; 248/223.41

(57) ABSTRACT

A board mounting apparatus includes: a guide mechanism which guides a pin electronic card along a horizontal direction to an inside of a test head; and an insert mechanism which moves a pin electronic card guided into the test head along a vertical direction so that the pin electronic card is electrically connected through connectors to a back board.

### TECHNICAL FIELD

The present invention relates to a board mounting apparatus for attaching a first circuit board to a second circuit board which is provided inside of a test head and detaching the same and relates to a test head and electronic device test apparatus which comprise the same.

### BACKGROUND ART

A test head of an electronic device test apparatus used for testing semiconductor integrated circuit devices and other electronic devices under test contains a large number of pin electronic cards. In such a test head, the pin electronic cards are inserted and taken out from above. For this reason, when replacing or repairing the pin electronic cards, the test head is inverted from a test position arranged on a prober to a maintenance position enabling access to the inside of the test head from above (for example, see PLT 1).

### CITATIONS LIST

### Patent Literature

PLT 1: Japanese Patent Publication (A) No. 2008-286657

### SUMMARY OF INVENTION

### Technical Problem

However, there was the problem that a manipulator or excess space was necessary for inverting the test head.

The problem to be solved by the present invention is the provision of a board mounting apparatus, test head, and electronic device test apparatus designed to enable reduction of the cost of and space occupied by an electronic device test apparatus.

### Solution to Problem

The board mounting apparatus according to the present invention is a board mounting apparatus for attaching a first circuit board to a second circuit board which is provided inside of a test head and detaching the same, characterized by comprising: a guide means for guiding the first circuit board along a first direction to the inside of the test head; and an inserting means for moving the first circuit board which is guided into the test head in a second direction which is substantially perpendicular to the first direction so that the first circuit board is electrically connected through a connector to the second circuit board.

In the above invention, the board mounting apparatus may further comprise: a biasing means for biasing the first circuit board which is guided by the guide means toward a direction away from the second circuit board.

In the above invention, the board mounting apparatus may further comprise: a fastening means for stopping movement of the first circuit board along the second direction.

In the above invention, the fastening means may fasten the first circuit board at a first position where the first circuit board is electrically connected through the connector to the second circuit board.

In the above invention, the fastening means may fasten the first circuit board at a second position where the first circuit board is separated from the second circuit board.

In the above invention, the fastening means may include a stopper which can slide along the first direction and the stopper may engage with a part of the guide means so as to fasten the first circuit board.

In the above invention, the board mounting apparatus may further comprise: a moving means for moving the inserting means with respect to a plurality of the guide means arranged in parallel along a third direction substantially perpendicular to the first and second directions.

In the above invention, the guide means may have: a guide rail provided along the first direction in the test head; and a contact member which is provided on the first circuit board and slides or rolls on the guide rail.

In the above invention, the inserting means may have: a slide member which has a cam follower and can slide along the first direction; and a movable member which is formed with a cam into which the cam follower is inserted and can move along the second direction relative to the slide member.

A test head according to the present invention is a test head which is electrically connected to an electronic device under test, characterized by comprising: a first circuit board; a second circuit board to which the first circuit board is electrically connected through a connector; and the above-mentioned board mounting apparatus which attaches the first circuit board to the second circuit board and detaches it.

An electronic device test apparatus according to the present invention is characterized by comprising: the above-mentioned test head; a tester body which is electrically connected to the test head and runs tests on an electronic device under test; and a transporting means for transporting an electronic device under test to the test head.

### Advantageous Effects of Invention

In the present invention, a guide means is used to guide a first circuit board along a first direction to the inside of a test head, and an inserting means is used to move the first circuit board along a second direction so that the first circuit board connect through a connector to the second circuit board.

For this reason, a first circuit board can be taken out of and inserted into the test head without inverting the test head to the maintenance position and no manipulator is required, so the electronic device test apparatus can be lowered in cost and reduced in occupied space.

### BRIEF DESCRIPTION OF DRAWINGS

FIG. 1 is a schematic cross-sectional view which shows an electronic device test apparatus in an embodiment of the present invention.

FIG. 2 is a cross-sectional view of a test head in an embodiment of the present invention.

FIG. 3 is a cross-sectional view along the line III-III of FIG. 2. [FIG. 4] FIG. 4 is a perspective view which shows a slide mechanism of a board mounting apparatus in an embodiment of the present invention.

FIG. 5A is a side view which shows an insert mechanism of a board mounting apparatus in an embodiment of the present invention and shows the insert mechanism in the raised state.

FIG. 5B is a side view which shows an insert mechanism of a board mounting apparatus in an embodiment of the present invention and shows the insert mechanism in the lowered state.

FIG. 6A is a side view which shows a stopper of a board mounting apparatus in an embodiment of the present invention and shows the state of fastening the slide mechanism at the lower limit position.

FIG. 6B is a side view which shows the state of release of the stopper from the state of FIG. 6A.

FIG. 7A is a side view which shows a stopper of a board mounting apparatus in an embodiment of the present invention and shows the state of fastening the slide mechanism at an upper limit position.

FIG. 7B is a side view which shows the state of release of the stopper from the state of FIG. 7A.

### DESCRIPTION OF EMBODIMENTS

Below, embodiments of the present invention will be explained on the basis of the drawings.

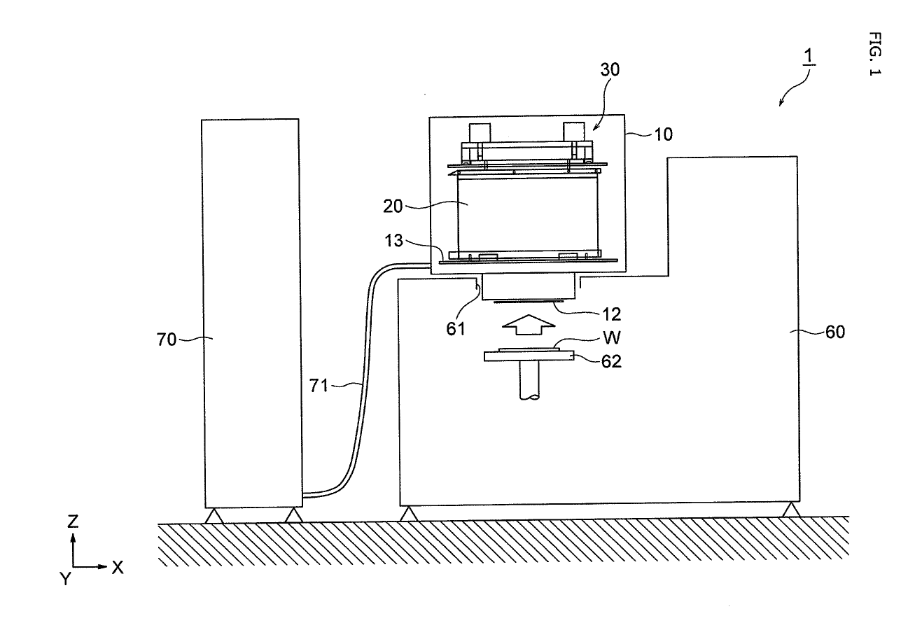

FIG. 1 is a schematic cross-sectional view which shows an electronic device test apparatus in the present embodiment.

The electronic device test apparatus 1 in the present embodiment is a test apparatus for so-called pre-processing use which tests a device under test (DUT) built into a semiconductor wafer W under test. As shown in FIG. 1, it comprises a test head 10, a prober 60, and a tester (main frame) 70.

The test head 10 has mounted in it a probe card 12 which is electrically connected to a DUT which is built into a semiconductor wafer W under test. In the present embodiment, this test head 10 is provided on the prober 60 at all times so that the probe card 12 approaches the inside of the prober 60 through an opening 61 regardless of whether it is the time for a test or the time for maintenance.

The prober 60 is designed to hold a semiconductor wafer W under test on a suction stage 62 and automatically feed it to a position which faces the probe card 12. Further, a tester 70 is electrically connected through a cable 71 to the test head 10 and enables signals to be input and output through the test head 10 with a DUT.

In the above configured electronic device test apparatus 1, the prober 60 is used to push the semiconductor wafer W under test against the probe card 12. In that state, the tester 70 supplies test signals to the DUT through the test head 10 and compares the signals output from the DUT (response signals) with the expected values so as to evaluate the electrical characteristics of the DUT.

Next, the configuration of the test head 10 in the present embodiment will be explained.

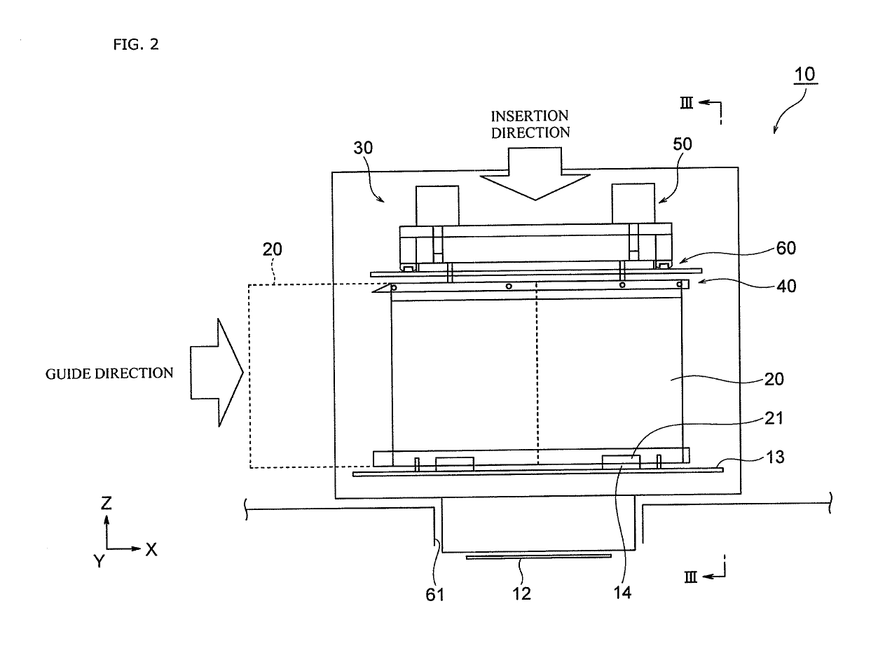

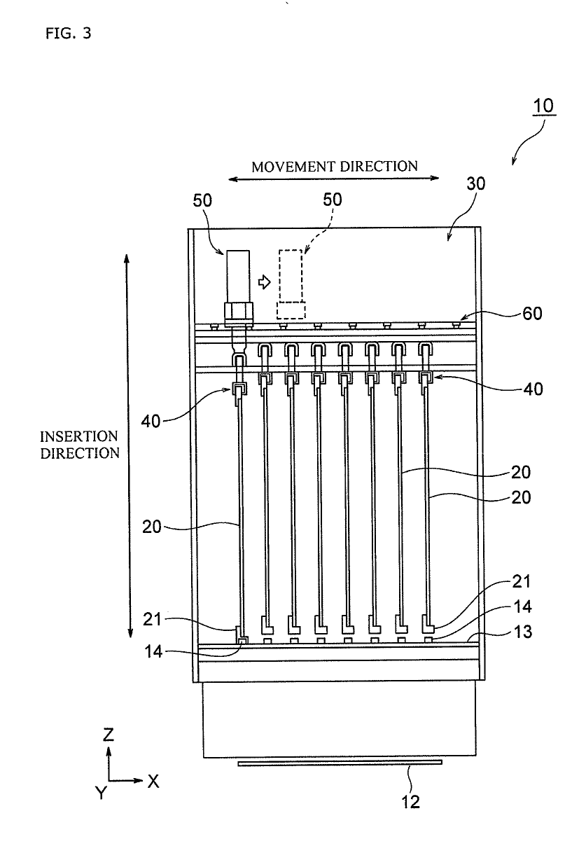

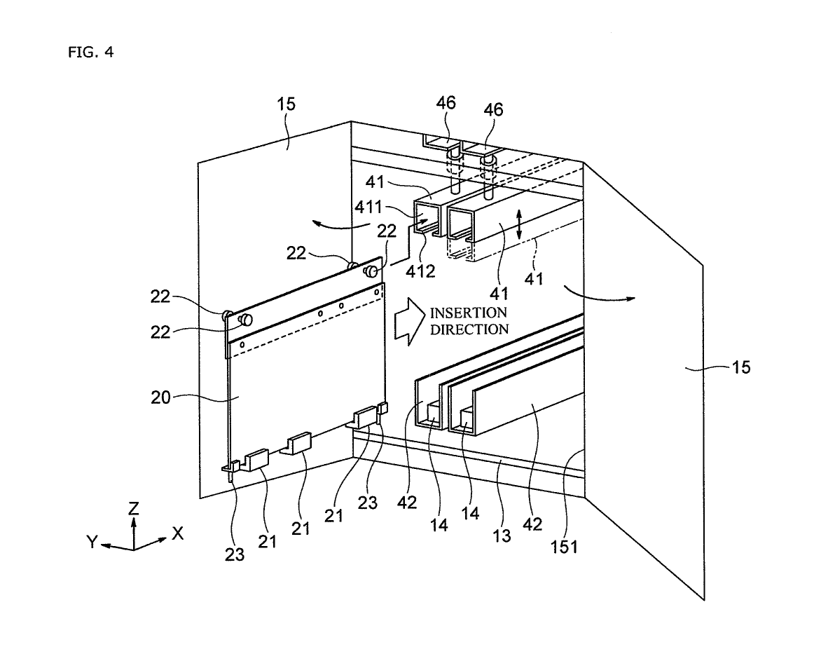

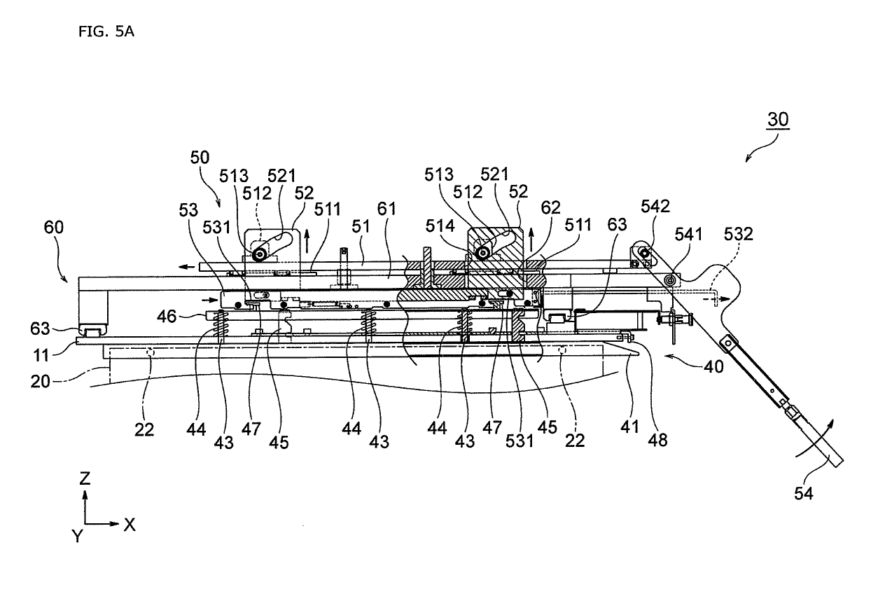

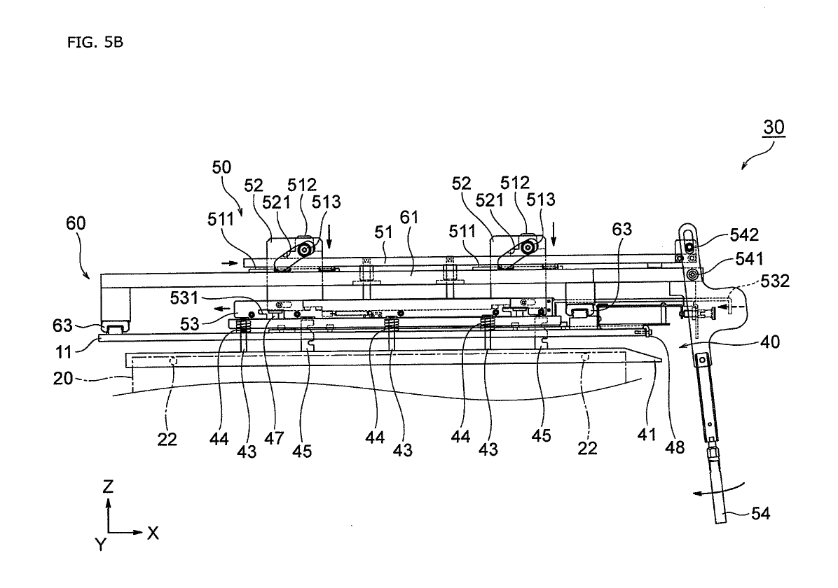

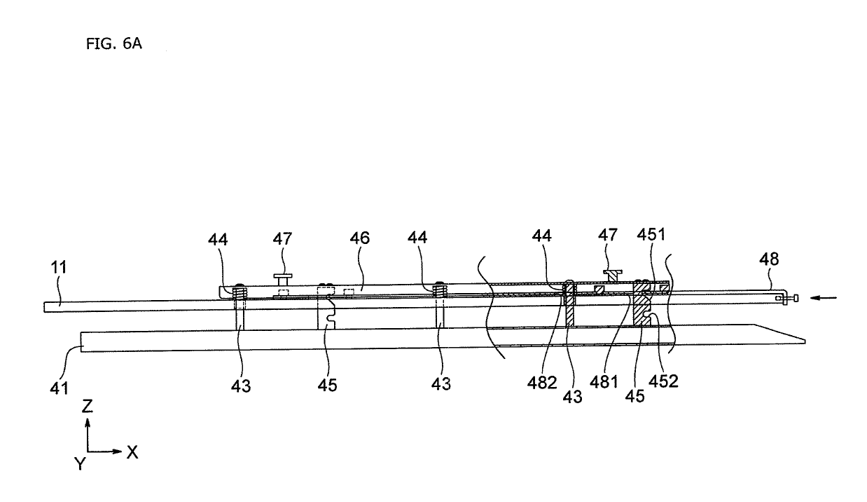

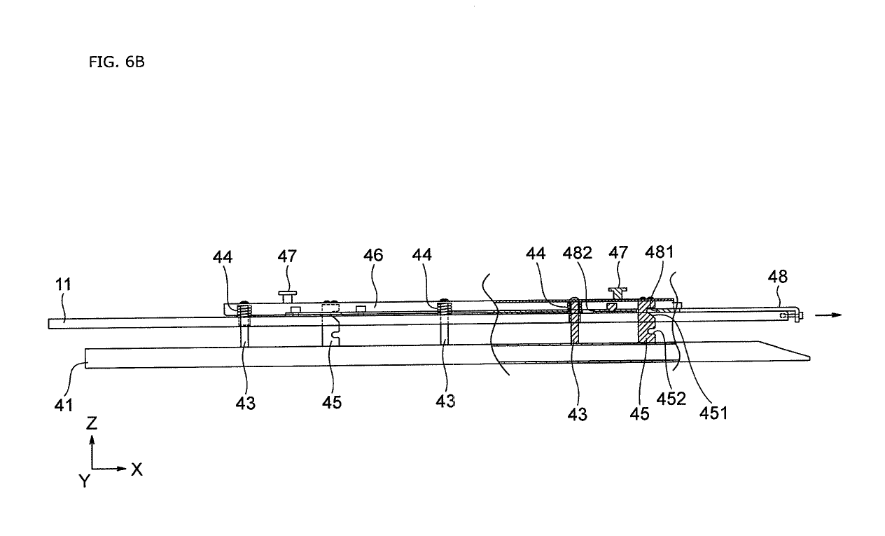

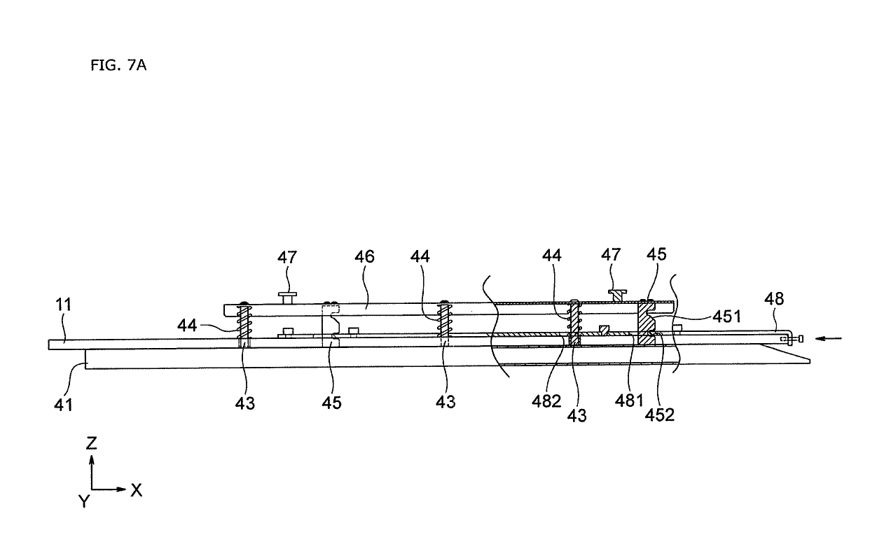

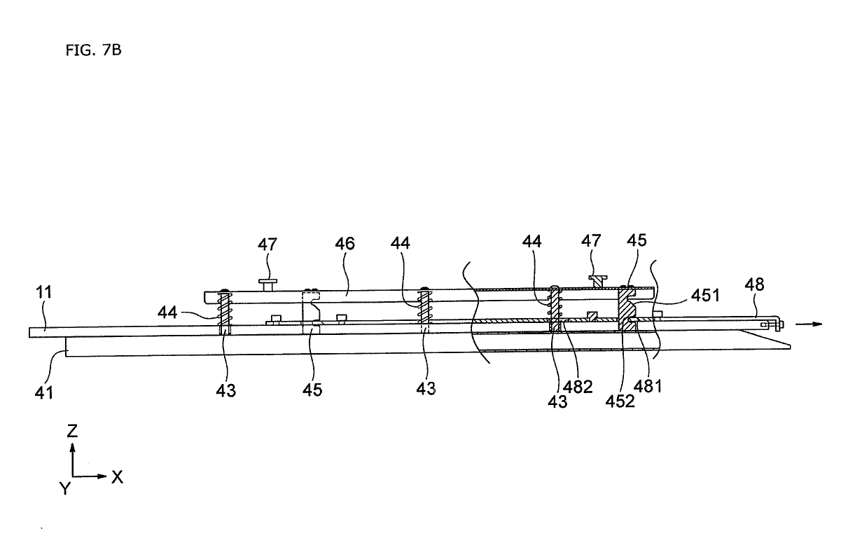

FIG. 2 is a cross-sectional view of a test head in the present embodiment, FIG. 3 is a cross-sectional view along the line of FIG. 2, FIG. 4 is a perspective view which shows a slide mechanism of a board mounting apparatus in the present embodiment, FIG. 5A and FIG. 5B are side views which show an insert mechanism of a board mounting apparatus in the present embodiment, and FIG. 6A to FIG. 7B are side views which show a stopper of a board mounting apparatus in the present embodiment.

As shown in FIG. 2 and FIG. 3, a back board 13 and a large number of pin electronic cards 20 are housed inside the test head 10 in the present embodiment.

The back board 13 is electrically connected through the cable 71 to the tester 70 (see FIG. 1) and is electrically connected to the probe card 12 through internal wiring not shown in particular. Further, connectors 14 which can be engaged with connectors 21 mounted on the pin electronic cards 20 are mounted on this back board 13. The back board 13 and the large number of pin electronic card 20 are electrically connected through the connectors 14 and 21.

Further, the test head 10 in the present embodiment, as shown in the figure, comprises a board mounting apparatus 30 which enables a pin electronic card 20 to be inserted to and taken out from the test head 10 along the horizontal direction (X-direction in the figure).

This board mounting apparatus 30 comprises: guide mechanisms 40 each of which guides a pin electronic card 20 inside the test head 10 in the horizontal direction (X-direction in the figure); an insert mechanism 50 which moves a pin electronic card 20 which was guided into the test head 10 in the vertical direction (Z-direction in the figure) so that the connectors 14 and 21 fit together or detach from each other; and a movement mechanism 60 which moves the insert mechanism 50 along a Y-direction in the figure.

Each of the guide mechanisms 40 of the board mounting apparatus 30, as shown in FIG. 4, comprises: upper and lower guide rails 41 and 42 which are provided along the X-direction in the figure; and rollers 22 provided at the top parts of the pin electronic cards 20.

The upper guide rail 41 is formed with a guide groove 411 from which ribs 412 stick out so as to face each other. The rollers 22 are rotatably attached to the pin electronic cards 20 through bearings etc.

When using a guide mechanism 40 to insert a pin electronic card 20 to the inside of the test head 10, the rollers 22 are inserted into the guide groove 411 of the upper guide rail 41. In that state, the pin electronic card 20 is pushed into the test head 10. By this, the rollers 22 roll inside of the guide groove 411 whereby the pin electronic card 20 is guided into the test head 10.

Incidentally, for example, door parts 15 configured from doors able to open and close as shown in FIG. 4 are provided at the side walls of the test head 10. In the state where these door parts 15 are opened, the pin electronic cards 20 are inserted through the opening 151 to the inside of the test head 10.

Note that, the rollers 22 which are inserted into a guide groove 411 are held by the ribs 412, so if the insert mechanism 50 causes a guide mechanism 40 as a whole to rise, along with this, the pin electronic card 20 is also lifted. Further, instead of bearings, it is possible to form the roller 22 by low friction members made of a resin material etc. In this case, the roller 22 slides on the insides of the upper guide rail 41.

On the other hand, the lower guide rails 42 are provided on the back board 13. By straddling connectors 21 with some clearance, the bottom parts of the pin electronic cards 20 are guided along the X-direction in the figure.

Note that, guide pins 23 stick out from the bottom part of each pin electronic card 20. The guide pins 23 are inserted into guide holes (not shown) which are formed in the back board 13 whereby the connectors 14 and 21 are positioned.

The board mounting apparatus 30 in the present embodiment comprises the same number of the above configured guide mechanisms 40 as the number of pin electronic cards 20 which are held in the test head 10.

As shown in FIG. 5A and FIG. 5B, in the guide mechanisms 40 of the present embodiment, a head 46 is attached to the upper guide rail 41 through connecting columns 43 and engagement columns 45. The insert mechanism 50 works through the head 46 to make the pin electronic card 20 which is held by the guide mechanisms 40 descend.

Furthermore, the head 46 is provided with hooks 47. The insert mechanism 50 makes the pin electronic card 20 rise while the hooks 47 engage with recesses 531 of the engagement members 53 explained later.

As shown in FIG. 6A to FIG. 7B, the connecting columns 43 and engagement columns 45 of the guide mechanisms 40 all pass through the frame 11 of the test head 10. Further, this frame 11 is provided with stoppers 48 which can slide along the horizontal direction (X-direction in the figure). The connecting columns 43 and engagement columns 45 pass though the stoppers 48 through engagement holes 481 and through holes 482.

Further, coil springs 44 are coaxially arranged around the connecting columns 43. Each of the coil springs 44 is interposed between the head 46 and the frame 11 of the test head 10. The head 46 is biased in a direction away from the frame 11. Due to this, when the guide mechanisms 40 are used to guide the pin electronic cards 20 into the test head 10, interference between the connectors 14 and 21 is prevented.

Each of the engagement columns 45 is formed with two notches 451 and 452. Further, if the stopper 48 is made to slide, the rims of the engagement holes 481 engage with first or second notches 451 or 452 whereby up and down movement of the guide mechanisms 4 due to the insert mechanism 50 is stopped. Incidentally, the through holes 482 of the stoppers 48 have sufficiently large inside diameters for the amount of sliding of the stoppers 48.

Specifically, as shown in FIG. 6A and FIG. 6B, if making a stopper 48 engage with the upper notches (first notches) 451 of the engagement columns 45, the guide mechanism 40 is stopped at the lower limit position (first position) whereby the state where the connectors 14 and 21 engage with each other and the back board 13 and pin electronic card 20 are electrically connected is maintained. Due to this, it is possible to prevent the engaged connectors 14 and 21 from ending up detaching due to the reaction force.

On the other hand, as shown in FIG. 7A and FIG. 7B, if making a stopper 48 engage with the lower notches (second notches) 452 of the engagement columns 45, the guide mechanism 40 is stopped at the upper limit position (second position) whereby interference between the connectors 14 and 21 is prevented when the guide mechanism 40 is used to guide the pin electronic card 20 into the test head 10.

The insert mechanism 50 of the board mounting apparatus 30, as shown in FIG. 5A and FIG. 5B, comprises a slide member 51, movable blocks 52, and engagement members 53.

The slide member 51 is provided to be able to slide, through a linear guide 511, on a later explained movement plate 61 of a movement mechanism 60 along the X-direction. A projecting part 512 sticks up from the top surface of the slide member 51. This projecting part 512 has a cam follower 513 rotatably attached to it.

The movable blocks 52 are inserted in the through holes 514 and 62 of the slide member 51 and movement plate 61 and are able to move relatively up and down with respect to the slide member 51 and movement plate 61. The movable blocks 52 are formed with cams 521 of shapes rising to the right in the figure. Cam followers 513 of the slide member 51 are inserted inside these cams 521 in a rollable manner.

Engagement members 53 slidable along the X-direction in the figure are attached to the bottom parts of the movable blocks 52. By pulling or pushing the handle 532, the engagement members 53 slide relative to the movable blocks 52. The engagement members 53 are formed with recesses 531 which engage with hooks 47 of the guide mechanisms 40. By making the engagement members 53 slide relative to the movable blocks 52, the hooks 47 and recesses 531 can be engaged and disengaged.

Furthermore, the insert mechanism 50 comprises a lever 54 for raising and lowering a pin electronic card 20. This lever 54 is attached in a pivoting manner to the slide member 51 and the movement mechanism 60 using one end of the movement mechanism 60 as a fulcrum 541 and one end of the slide member 51 as a power point.

When the insert mechanism 50 is used to make a pin electronic card 20 descend, as shown in FIG. 5B, the lever 54 is pushed down to make the lever 54 pivot clockwise in the figure about the fulcrum 541. Due to this, the slide member 51 slides to the right side in the figure whereby the cam followers 513 roll in the cams 521 and the movable blocks 52 descend relative to the frame 11 of the test head 10. Due to this, the movable blocks 52 push the head 46 down, so the pin electronic card 20 which is held by the upper guide rail 41 also descends. Further, if the connectors 14 and 21 engage, the pin electronic card 20 is electrically connected to the back board 13.

On the other hand, when the insert mechanism 50 is used to make a pin electronic card 20 ascend, as shown in FIG. 5A, first, the handle 532 is pulled to the right in the figure to make the recesses 531 of the engagement members 53 engage with the hooks 47 of the guide mechanism 40. Next, the lever 54 is raised to make the lever 54 pivot counterclockwise in the figure about the fulcrum 541. Due to this, the slide member 51 slides to the left in the figure whereby the cam followers 513 roll in the cams 521, the movable blocks 52 rise relative to the frame 11, and the head 46 is pulled up. Due to this, the pin electronic card 20 which is held by the upper guide rail 41 also rises, so the connectors 14 and 21 which connect the pin electronic card 20 and back board 13 are disengaged.

Note that, in the present embodiment, a cam type of insert mechanism 50 was explained, but the invention is not particularly limited to this. For example, an air cylinder driving movement in the up-down direction or other actuator may be used to form the insert mechanism. Further, in the present embodiment, the insert mechanism 50 was driven manually, but the invention is not particularly limited to this. For example, a motor etc. may also be used to drive the insert mechanism.

The movement mechanism 60 of the board mounting apparatus 30 comprises: a movement plate 61 on which the above-mentioned insert mechanism 50 is provided; and a linear guide 63 which is interposed between this movement plate 61 and the frame 11 of the test head 10. The movement plate 61 can slide on the frame 11 along the Y-direction due to the linear guide 63. Due to the movement mechanism 60, the insert mechanism 50 can move along the Y-direction in the figure, so a single insert mechanism 50 can be used to handle a plurality of guide mechanisms 40.

Specifically, as shown in FIG. 4, when a single guide mechanism 40 is used to guide a pin electronic card 20 inside the test head 10, as shown in FIG. 5B, the insert mechanism 50 pushes down the pin electronic card 20 and the connectors 14 and 21 engage to electrically connect the pin electronic card 20 to the back board 13. In this state, as shown in FIG. 6A, the stopper 48 is made to slide to the left side in the figure to make it engage with the first notches 451 of the engagement columns 45 and fasten the guide mechanism 40. Due to this, even without the insert mechanism 50, the connected state of the pin electronic card 20 and back board 13 is maintained.

Next, the movement mechanism 60 is used to make the insert mechanism 50 move above the adjoining guide mechanism 40 (see FIG. 3) and the same procedure is followed to electrically connect a pin electronic card 20 to the back board 13. In this state, a stopper 48 is used to fasten the guide mechanism 40. By repeating this operation, a single insert mechanism 50 can be used to handle a plurality of guide mechanisms 40.

In the above way, in the present embodiment, a guide mechanism 40 is used to guide a pin electronic card 20 along the horizontal direction (X-direction in the figure) to the inside of the test head 10, then the insert mechanism 50 is used to make the pin electronic card 20 move along the vertical direction (Z-direction in the figure) to electrically connect the pin electronic card 20 to the back board 13 through the connectors 14 and 11.

For this reason, without inverting the test head 10 to the maintenance position, a pin electronic card 20 can be inserted into and taken out from the test head 10. No manipulator is required, so the costs of the electronic device test apparatus 1 can be lowered and the occupied space reduced.

Note that, the embodiments which were explained above were described for facilitating understanding of the present invention and were not described for limiting the present invention. Therefore, the elements which are disclosed in the embodiments include all design changes and equivalents which fall under the technical scope of the present invention.

For example, in the above-mentioned embodiments, the explanation was given with respect to the example of application of the board mounting apparatus to a test apparatus for pre processing use for testing a DUT in a state built into a semiconductor wafer, but the invention is not particularly limited to this. For example, the board mounting apparatus may also be applied to a test apparatus for post processing use for testing a packaged DUT.

Further, the above-mentioned embodiments, the explanation was given with respect to the first and third directions as the horizontal directions and the second direction as the vertical direction, but the invention is not particularly limited to this so long as the correspondence among the first to third directions stands.

### Reference Signs List

1 . . . electronic device test apparatus

10 . . . test head
11 . . . frame
13 . . . back board (second circuit board)
14 . . . connector
15 . . . door part

20 . . . pin electronic card (first circuit board)
21 . . . connector
22 . . . roller (contact member)

30 . . . board mounting apparatus

40 . . . guide mechanism (guide means)
41 . . . upper guide rail
44 . . . coil spring (biasing means)
48 . . . stopper (fastening means)

50 . . . insert mechanism (inserting means)

51 . . . slide member
513 . . . cam follower
514 . . . through hole

52 . . . movable block (movable member)
521 . . . cam

53 . . . engagement member

54 . . . lever

60 . . . movement mechanism (moving means)

1. A board mounting apparatus configured to attach a first circuit board to a second circuit board which is provided inside of a test head to detach the first circuit board from the second circuit board, the board mounting apparatus comprising:
a guide device configured to guide the first circuit board along a first direction to the inside of the test head; and
an inserting device configured to move the first circuit board which is guided into the test head in a second direction which is substantially perpendicular to the first direction so that the first circuit board is electrically connected through a connector to the second circuit board.

2. The board mounting apparatus as set forth in claim 1, further comprising: a biasing device configured to bias the first circuit board which is guided by the guide device toward a direction away from the second circuit board.

3. The board mounting apparatus as set forth in claim 1, further comprising: a fastening device configured to stop movement of the first circuit board along the second direction.

4. The board mounting apparatus as set forth in claim 3, wherein the fastening device fastens the first circuit board at a first position where the first circuit board is electrically connected through the connector to the second circuit board.

5. The board mounting apparatus as set forth in claim 3, wherein the fastening device fastens the first circuit board at a second position where the first circuit board is separated from the second circuit board.

6. The board mounting apparatus as set forth in claim 3, wherein
the fastening device includes a stopper which can slide along the first direction and
the stopper engages with a part of the guide device so as to fasten the first circuit board.

7. The board mounting apparatus as set forth in claim 1, further comprising: a moving device configured to move the inserting device with respect to a plurality of the guide device arranged in parallel along a third direction substantially perpendicular to the first and second directions.

8. The board mounting apparatus as set forth in claim 1, wherein the guide device has:
a guide rail provided along the first direction in the test head; and
a contact member which is provided on the first circuit board and slides or rolls on the guide rail.

9. The board mounting apparatus as set forth in claim 1, wherein the inserting device has:
a slide member which has a cam follower and can slide along the first direction; and
a movable member which is formed with a cam into which the cam follower is inserted and can move along the second direction relative to the slide member.

10. A test head which is electrically connected to an electronic device under test, the test head comprising:
a first circuit board;
a second circuit board to which the first circuit board is electrically connected through a connector; and
the board mounting apparatus as set forth in claim 1 which attaches the first circuit board to the second circuit board and detaches the first circuit board from the second circuit board.

11. An electronic device test apparatus comprising:
the test head as set forth in claim 10;
a tester body which is electrically connected to the test head and runs tests on an electronic device under test; and
a transporting device configured to transport an electronic device under test to the test head.
